(19) United States
(12) Patent Application Publication
(10) Pub. No.: US 2022/0190739 A1
(43) Pub. Date: Jun. 16, 2022

(54) POWER CONVERSION APPARATUS

(71) Applicants: KABUSHIKI KAISHA TOSHIBA, Tokyo (JP); Toshiba Infrastructure Systems & Solutions Corporation, Kawasaki-shi (JP)

(72) Inventors: Takashi TAKAGI, Kawasaki (JP); Keita NAKANISHI, Fuchu (JP)

(73) Assignees: KABUSHIKI KAISHA TOSHIBA, Tokyo (JP); Toshiba Infrastructure Systems & Solutions Corporation, Kawasaki-shi (JP)

(21) Appl. No.: 17/476,145

(22) Filed: Sep. 15, 2021

(30) Foreign Application Priority Data
Dec. 14, 2020 (JP) 2020-206762

(51) Int. Cl. H02M 7/5387; H02M 1/00; H02M 1/08

(52) U.S. Cl. CPC H02M 7/5387; H02M 1/0009; H03K 19/21; H02M 1/0012; H02M 1/08

(57) ABSTRACT

A power conversion apparatus includes a power conversion circuit including a semiconductor element in each of upper and lower arms between DC links, and being electrically connected to an AC load at an AC end. A voltage detector detects a voltage between the DC links. A current detector detects a current flowing in the AC end. A control unit generates a gate command based on a voltage value obtained by the voltage detector and a current value obtained by the current detector. A gate driver drives the semiconductor element based on the gate command, includes a gate current detector and a circuit to determine a drive state of the semiconductor element from the gate current, and outputs a value corresponding to the drive state to the control unit.

### CROSS-REFERENCE TO RELATED APPLICATIONS

This application is based upon and claims the benefit of priority from Japanese Patent Application No. 2020-206762, filed Dec. 14, 2020, the entire contents of which are incorporated herein by reference.

### FIELD

Embodiments described herein relate generally to a power conversion apparatus.

### BACKGROUND

In a power conversion apparatus, if an overcurrent is generated as a result of a failure and/or abnormality that has occurred in a device equipped with the power conversion apparatus, not only the device but also a power supply source and a device to be controlled may be seriously damaged. Therefore, it is desirable that an abnormality in the device be detected immediately so measures can be taken such as, for example, stopping operation of the power conversion apparatus, opening a circuit, or the like. The failure rate is high particularly in the periphery of a semiconductor element, and therefore it is desirable that the power conversion apparatus include means for detecting a failure or abnormality in the semiconductor element.

Conventionally, means for detecting a gate voltage of an insulated gate type semiconductor element, determining whether the gate voltage is at a high level or a low level, and, based on a logical mismatch between a gate command signal and the gate voltage, determining that an abnormality occurs in the semiconductor element has been proposed.

According to the conventional method for determining a driving state of a semiconductor element by detecting a gate voltage, for example, in the case where a circuit (gate wiring) that connects a gate driver to the semiconductor element is disconnected, not a gate voltage of the semiconductor element but an output voltage of the gate driver is detected. This makes it impossible to detect not only a driving state of the semiconductor element but also the presence or absence of disconnection.

Furthermore, in recent years, while the miniaturization of semiconductor element packages has progressed, the demanded conversion capacity of power conversion apparatuses has tended to increase. To meet this demand, the capacity of a power conversion apparatus is being increased by mounting thereon an element package in which a plurality of semiconductor elements are connected in parallel. In general, a gate resistor is inserted in series in a circuit that connects a semiconductor element to a gate driver. In a power conversion apparatus in which semiconductor elements for respective arms are connected in parallel, it is desirable to connect a gate resistor to each of the semiconductor elements in order to match the dynamic characteristics between the semiconductor elements as much as possible. In the case where the conventional method of detecting a gate voltage to determine a driving state of a semiconductor element is adopted in the power conversion apparatus described in the above, a gate voltage detection circuit needs to be provided for each semiconductor element.

### BRIEF DESCRIPTION OF THE DRAWINGS

FIG. 1 is a schematic diagram showing a configuration example of a power conversion apparatus according to one embodiment.

FIG. 2 is a diagram for illustrating a configuration example of a gate driver of the power conversion apparatus shown in FIG. 1.

FIG. 3 is a diagram for illustrating an example of operation of the power conversion apparatus according to one embodiment.

FIG. 4 is a diagram for illustrating another example of operation of the power conversion apparatus according to one embodiment.

FIG. 5 is a diagram for illustrating yet another example of operation of the power conversion apparatus according to one embodiment.

FIG. 6 is a schematic diagram showing another configuration example of the power conversion apparatus and its gate driver according to one embodiment.

### DETAILED DESCRIPTION

In general, according to one embodiment, a power conversion apparatus includes: a power conversion circuit; a voltage detector; a current detector; a control unit; and a gate driver. The power conversion circuit includes a semiconductor element arranged in each of an upper arm and a lower arm between DC links, and is electrically connected to an AC load at an AC end between the upper arm and the lower arm. The voltage detector is configured to detect a voltage between the DC links. The current detector is configured to detect a current flowing in the AC end. The control unit is configured to generate a gate command for instructing operation of the semiconductor element based on a voltage value obtained by the voltage detector and a current value obtained by the current detector. The gate driver is configured to drive the semiconductor element based on the gate command, and includes a gate current detector configured to detect a gate current of the semiconductor element and a circuit configured to determine a drive state of the semiconductor element from the gate current. The gate driver outputs a value corresponding to the drive state to the control unit.

Hereinafter, a power conversion apparatus of an embodiment will be described with reference to the accompanying drawings.

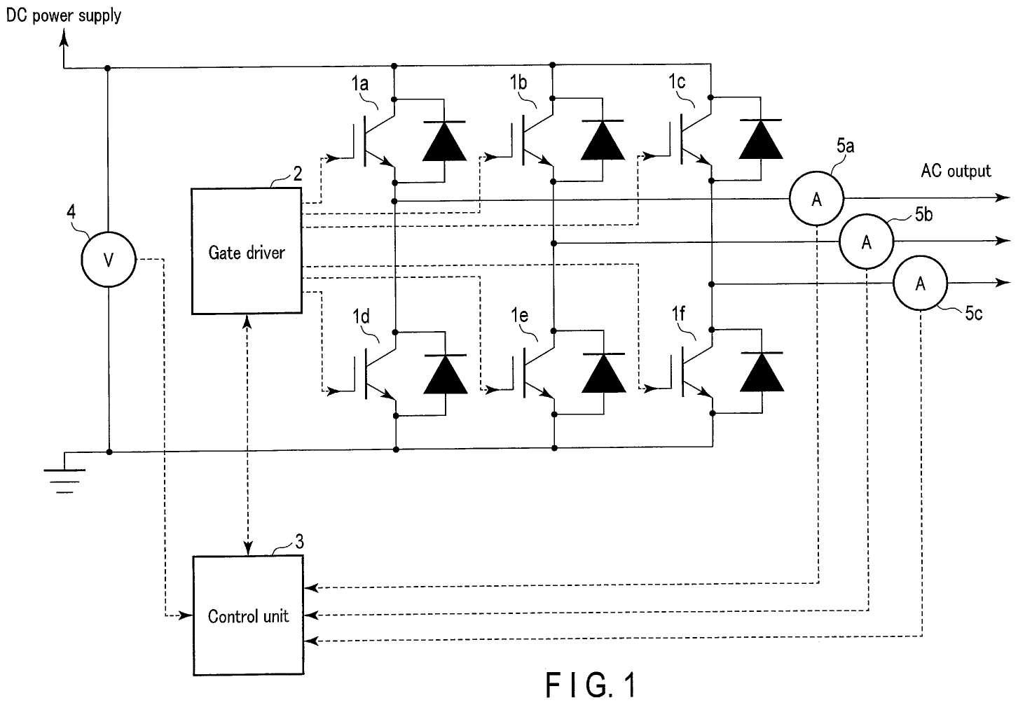

FIG. 1 is a schematic diagram showing a configuration example of a power conversion apparatus according to one embodiment.

The power conversion apparatus according to the present embodiment is a two-level three-phase inverter including: a power conversion circuit that is connected between a DC power supply and an AC load (neither is shown) (or is connected between a DC load and an AC power supply) and includes a plurality of semiconductor elements 1a to 1f; a gate driver 2; a control unit 3; a voltage detection unit (voltage detector) 4; and current detection units (current detectors) Sa to 5c.

The power conversion circuit includes: a DC link on a high potential side that is electrically connected to a positive terminal of the DC power supply; a DC link on a low potential side that is electrically connected to a negative terminal (earth) of the DC power supply; each phase leg that is connected between the DC links; and each phase AC line that is electrically connected between the AC load and a node between an upper arm and a lower arm of each phase leg.

The plurality of semiconductor elements 1a to 1f are voltage-driven type semiconductor elements, and include, for example, semiconductor elements such as a metal-oxide-semiconductor field-effect transistor (MOSFET) and an insulated gate bipolar transistor (IGBT). The plurality of semiconductor elements 1a to 1f are respectively arranged in the respective upper arms and the respective lower arms of the three-phase legs of the power conversion apparatus. That is, the semiconductor element 1a is arranged in a U-phase upper arm, and the semiconductor element 1d is arranged in a U-phase lower arm. The semiconductor element 1b is arranged in a V-phase upper arm, and the semiconductor element 1e is arranged in a V-phase lower arm. The semiconductor element 1c is arranged in a W-phase upper arm, and the semiconductor element 1f is arranged in a W-phase lower arm. Gates of the semiconductor elements 1a to 1f are electrically connected to the gate driver 2 with gate wirings.

The voltage detection unit 4 detects a voltage between the DC links of the power conversion apparatus (DC power supply voltage). Voltage values detected by the voltage detection unit 4 are supplied to the control unit 3.

The current detection units 5a to 5c each detect each phase current flowing between the power conversion apparatus and the AC load. The current detection unit 5a detects a U-phase current flowing in a U-phase AC line between the power conversion apparatus and the AC load. The current detection unit 5b detects a V-phase current flowing in a V-phase AC line between the power conversion apparatus and the AC load. The current detection unit Sc detects a W-phase current flowing in a W-phase AC line between the power conversion apparatus and the AC load. Current values detected by the current detection units 5a to 5c are supplied to the control unit 3. It suffices that the power conversion apparatus includes current detection units that detect at least two-phase AC currents, and any one of the current detection units 5a-5c may be omitted.

The control unit 3 receives a voltage value of the DC power supply and AC current values output from the power conversion apparatus, generates, for example, a gate command in accordance with an output requested from a higher-level control device (not shown), and outputs the gate command to the gate driver 2.

The control unit 3 includes at least one processor and a memory in which a program to be executed by the processor is stored, and may include an arithmetic circuit that is configured to realize various functions by software or combination of software and hardware.

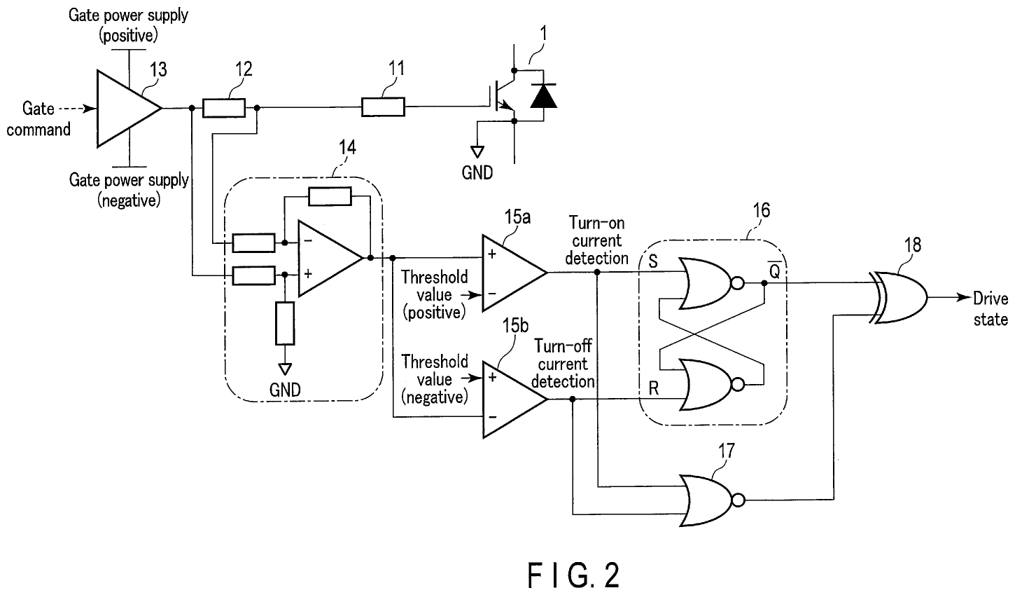

The gate driver 2 generates gate signals by using the gate command supplied from the control unit 3 and outputs the gate signals to the gate wirings. The gate driver 2 includes driver circuits (shown in FIG. 2) respectively corresponding to the semiconductor elements 1a to 1f.

FIG. 2 is a diagram for illustrating a configuration example of a gate driver of the power conversion apparatus shown in FIG. 1.

FIG. 2 shows a configuration example of a single driver circuit included in the gate driver 2. The semiconductor element 1 driven by the driver circuit may be one of the semiconductor elements 1a to 1f.

The driver circuit includes a gate resistor 11, a shunt resistor (gate current detector) 12, a gate drive circuit 13, a differential amplifier circuit 14, comparators 15a and 15b, a set reset flip-flop (RS-FF) circuit 16, a NOR gate circuit (negative logic sum gate circuit) 17, and an EXOR gate circuit (exclusive logic sum gate circuit) 18.

The gate resistor 11 is connected in series to the gate wiring that supplies a gate signal to a gate of the semiconductor element 1. The gate resistor 11 suppresses a current flowing into the gate of the semiconductor element 1.

The shunt resistor 12 is interposed between an output end of the gate drive circuit 13 and the gate resistor 11. Potentials at both ends of the shunt resistor 12 are supplied to the differential amplifier circuit 14.

The gate drive circuit 13 uses a gate power supply on a positive side and a gate power supply on a negative side to generate a gate signal (voltage) corresponding to a gate command output from the control unit 3, thereby outputting the gate signal to the gate of the semiconductor element 1.

The differential amplifier circuit 14 amplifies and outputs a voltage of the shunt resistor 12 by using potential values at both ends of the shunt resistor 12. The shunt resistor 12 is, for example, a low resistance of 100 mΩ or less, and a voltage generated between both ends of the shunt resistor 12 is equal to or less than 1 V. The differential amplifier circuit 14 amplifies a voltage between both ends of the shunt resistor 12 to a voltage with which signal is easily processed, and outputs the amplified voltage.

In the comparator (turn-on current detection circuit) 15a, an output value of the differential amplifier circuit 14 is input to a positive input terminal, and a threshold value (>0) is input to a negative input terminal. That is, an output value of the comparator 15a becomes positive when a positive current exceeding a predetermined threshold value is flowing into the gate of the semiconductor element 1, which makes it possible to detect a positive current corresponding to a turn-on flowing into the gate of the semiconductor element 1.

In the comparator (turn-off current detection circuit) 15b, a threshold value (<0) is input to a positive input terminal, and an output value of the differential amplifier circuit 14 is input to a negative input terminal. That is, an output value of the comparator 15b becomes positive when a negative current less than a predetermined threshold value is flowing into the gate of the semiconductor element 1, which makes it possible to detect a negative current corresponding to turn-off flowing into the gate of the semiconductor element 1.

In the set reset flip-flop circuit 16, an output value of the comparator 15a is input to a set (S) terminal, an output value of the comparator 15b is input to a reset (R) terminal, and a negative value of an input of the set (S) terminal is output. Therefore, when an output value of the comparator 15a is equal to “1 (>0)” and an output value of the comparator 15b is equal to “0 (<0)”, an output of the set reset flip-flop circuit 16 becomes “0”. When an output value of the comparator 15a is equal to “0 (<0)” and an output value of the comparator 15b is equal to “1 (>0)”, an output Q of the set reset flip-flop circuit 16 becomes “1”. When both the output value of the comparator 15a and the output value of the comparator 15b are equal to “0 (<0)”, an output of the set reset flip-flop circuit 16 is maintained.

The NOR gate circuit 17 outputs a negative value of a logical sum of the output value of the comparator 15a and the output value of the comparator 15b. Therefore, when the output value of the comparator 15a and the output value of the comparator 15b are equal to “0 (<0)”, the output value of the NOR gate circuit 17 becomes “1”. Otherwise, the output value of the NOR gate circuit 17 is equal to “0”.

The EXOR gate circuit 18 outputs an exclusive logic sum of the output value of the set reset flip-flop circuit 16 and the output value of the NOR gate circuit 17. Therefore, when either the output value of the set reset flip-flop circuit 16 or the output value of the NOR gate circuit 17 is equal to “1”, the output value of the EXOR gate circuit 18 becomes “1”. When both the output value of the set reset flip-flop circuit 16 and the output value of the NOR gate circuit 17 are equal to “1” or equal to “0”, the output value of the EXOR gate circuit 18 becomes “0”. The output value of the EXOR gate circuit 18 is output as a drive state (value corresponding to the drive state) of the semiconductor element 1.

Drive states of the plurality of semiconductor elements 1 output from the gate driver 2 are input to, for example, the control unit 3. The control unit 3 compares a gate command with a drive state of each semiconductor element 1 and detects an abnormality in the semiconductor element 1, the gate driver 2, and the wiring (gate wiring) electrically connected between the semiconductor element 1 and the gate driver 2. In the case of detecting an abnormality in the semiconductor element 1 and the periphery of the semiconductor element 1, for example, the control unit 3 may stop the power conversion apparatus abnormally and notify a higher-level control apparatus (not shown) of the abnormality of the power conversion apparatus.

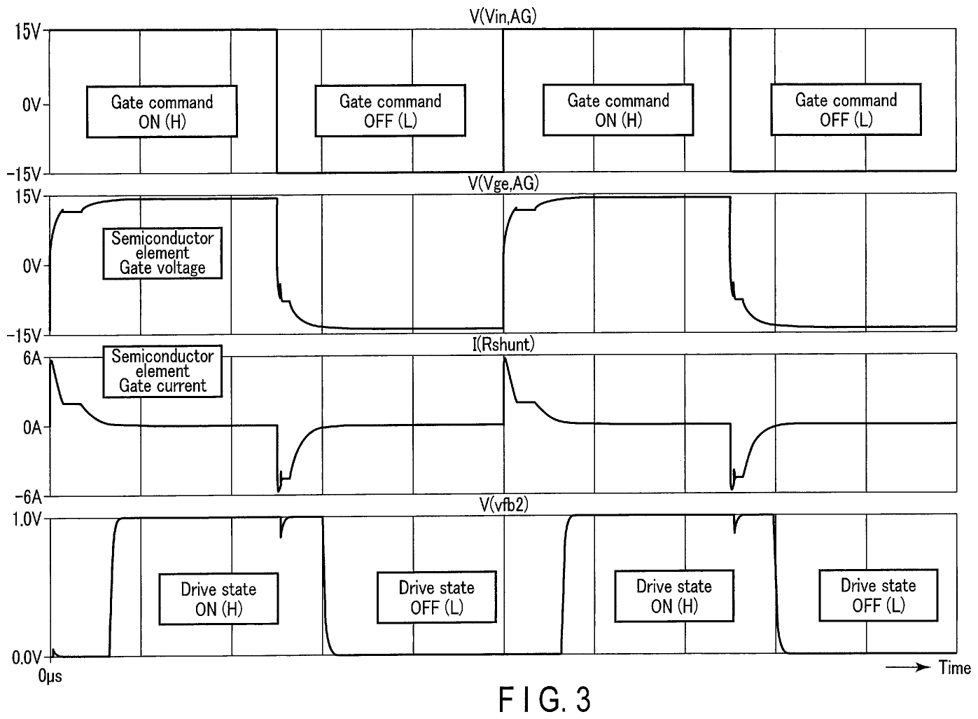

FIG. 3 is a diagram for illustrating an example of operation of the power conversion apparatus according to one embodiment.

FIG. 3 shows exemplary waveforms of a gate command Vin output from the control unit 3, a gate voltage Vge of the semiconductor element 1, a gate current Ishunt of the semiconductor element 1, and a drive state vfb2 of the semiconductor element 1, which are observed when the semiconductor element 1 is operating normally.

When the gate command Vin is caused to transition from ON to OFF to ON to OFF, the gate voltage Vge of the semiconductor element 1 also transitions from high (H) to low (L) to high (H) to low (L) in synchronization with the gate command Vin.

For example, a gate portion of an insulated gate type semiconductor element is approximately equivalent to a charging and discharging circuit of a capacitor. Therefore, the gate current Ishunt of the semiconductor element 1 flows as a positive current only at the time immediately after the gate command Vin is switched from OFF to ON, and flows as a negative current only at the time immediately after the gate command Vin is switched from ON to OFF. In both times, the gate current Ishunt converges to zero [A] over time. In the present embodiment, the direction of a current flowing from the gate driver 2 to the semiconductor element 1 is set treated as positive.

In response to a gate current converging to the vicinity of zero [A] (below the threshold value), which is triggered by energization of a positive or negative gate current, the drive state vfb2 is switched in logic between high (H) and low (L). According to this, when the gate command is caused to transition from ON to OFF to ON to OFF, although there is an operation delay, the drive state vfb2 also transitions from ON to OFF to ON to OFF, resulting in the same logical value as the gate command Vin.

Accordingly, in the power conversion apparatus of the present embodiment, the control unit 3 detects the logical mismatch between the gate command Vin and the drive state vfb2, thereby being able to determine an abnormality in the semiconductor element 1, the gate driver 2, and the wiring (gate wiring) between the semiconductor element 1 and the gate driver 2.

For example, when an overcurrent occurs during a turn-on of the semiconductor element 1, in the case of the semiconductor element 1 being an insulated gate bipolar transistor (IGBT), a potential difference between a collector and an emitter rises sharply and accordingly, and in accordance with this, a negative gate current flowsin the semiconductor element 1 through a feedback capacitance (capacitance between the collector and the gate). Therefore, when the semiconductor element 1 is driven normally, the gate current gradually converges to zero [A] after a turn-on, whereas, when an overcurrent occurs, the gate current does not gradually converge to zero [A] and a predetermined value (below the threshold value) is detected immediately after the turn-on, so that the logic of the drive state vfb2 is inverted. This makes it possible to detect a logical mismatch between the gate command Vin and the drive state vfb2.

Furthermore, for example, when the wiring (gate wiring) between the gate driver 2 and the semiconductor element 1 is broken, the gate current does not flow and thus cannot be detected. For this reason, the drive state vfb2 is fixed to high (H) or low (L), so that an abnormality in the semiconductor element 1 can be detected through a logical mismatch between the gate command Vin and the drive state vfb2.

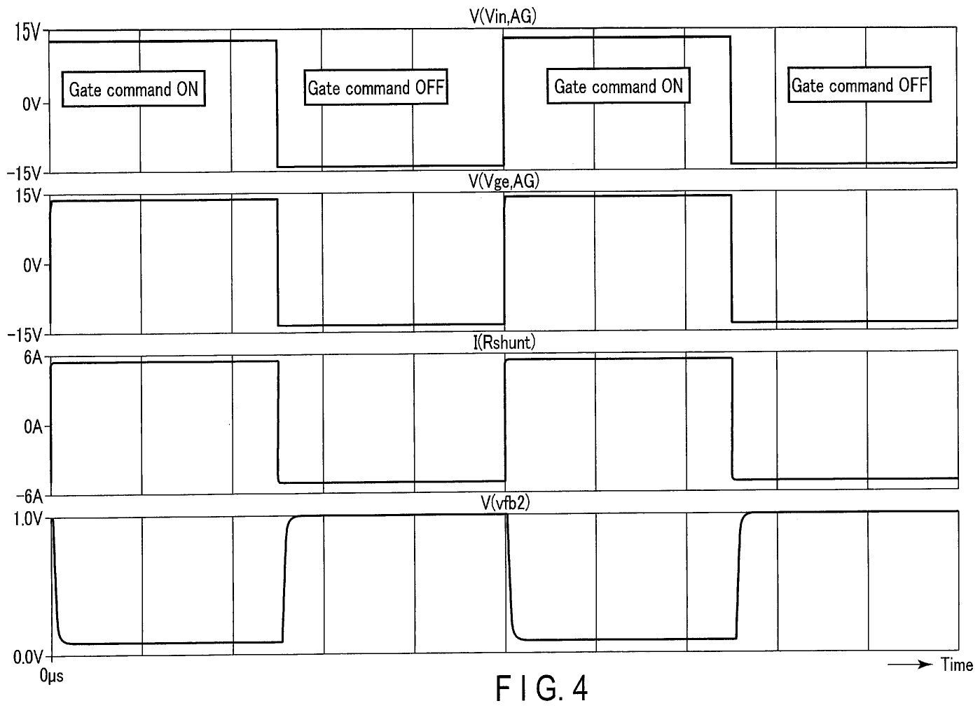

FIG. 4 is a diagram for illustrating another example of operation of the power conversion apparatus according to the one embodiment.

FIG. 4 shows exemplary waveforms of a gate command Vin output from the control unit 3, a gate voltage Vge of the semiconductor element 1, a gate current Ishunt of the semiconductor element 1, and a drive state vfb2 of the semiconductor element 1, which are observed when the gate of the semiconductor element 1 is short-circuited.

When the gate command Vin is caused to transition from ON to OFF to ON to OFF, the gate voltage Vge of the semiconductor element 1 also transitions from high (H) to low (L) to high (H) to low (L) in synchronization with the gate command Vin.

Furthermore, since the gate is short-circuited, the gate current Ishunt of the semiconductor element 1 makes the same transition as that of the gate command Vin. That is, a positive current flows while the gate command Vin is ON, and a negative current flows while the gate command Vin is OFF. In the present embodiment, the direction of a current flowing from the gate driver 2 to the semiconductor element 1 is treated as positive.

As a result of the above, the drive state vfb2 exhibits a waveform obtained by inverting a waveform of the gate command Vin. That is, when the gate command is caused to transition from ON to OFF to ON to OFF, the drive state vfb2 transitions from OFF to ON to OFF to ON and does not correspond to the gate command Vin in terms of transition.

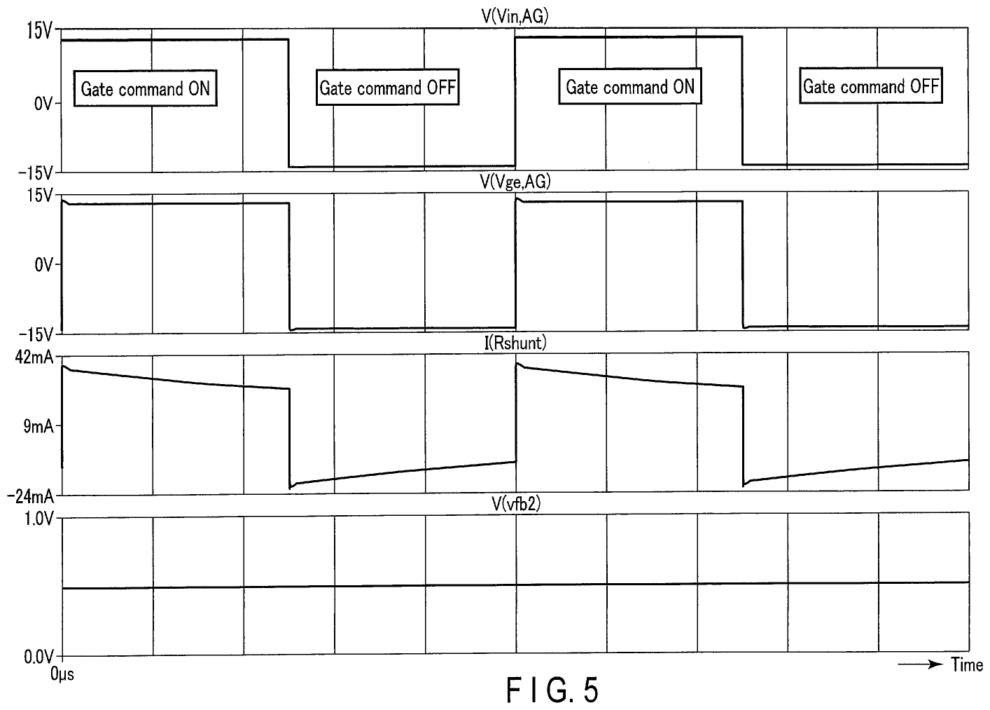

FIG. 5 is a diagram for illustrating yet another example of operation of the power conversion apparatus according to one embodiment.

FIG. 5 shows exemplary waveforms of a gate command Vin output from the control unit 3, a gate voltage Vge of the semiconductor element 1, a gate current Ishunt of the semiconductor element 1, and the drive state vfb2 of the semiconductor element 1, which are observed when the gate of the semiconductor element 1 is open.

When the gate command Vin is caused to transition from ON to OFF to ON to OFF, the gate voltage Vge of the semiconductor element 1 also transitions from high (H) to low (L) to high (H) to low (L) in synchronization with the gate command Vin.

Furthermore, since the gate of the semiconductor element 1 is open, the gate current Ishunt hardly flows. In the example shown in FIG. 5, a minute current value is detected because of the potential difference between both ends of the shunt resistor 12.

As a result of the above, the drive state vfb2 is fixed to a constant value, so that an abnormality in the semiconductor element 1 and its periphery can be detected through a logical mismatch between the gate command Vin and the drive state vfb2.

As described in the above, in the power conversion apparatus according to the present embodiment, the gate driver 2 includes gate current detecting means using the shunt resistor 12, detects convergence from energization of the gate current using the logic circuit, detects a drive state of the semiconductor element 1 using a gate current value, and detects an abnormality in the semiconductor element 1 and its periphery by the control unit 3 using a logical mismatch between a gate command and the drive state.

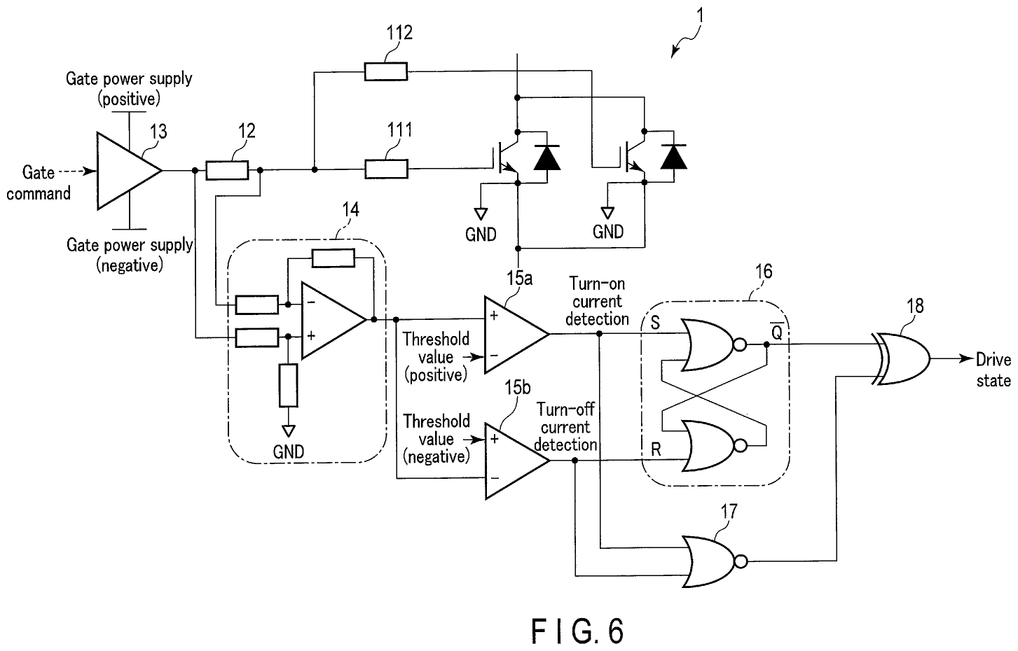

FIG. 6 is a schematic diagram showing another configuration example of the power conversion apparatus and its gate driver according to one embodiment.

FIG. 6 shows an example in which the semiconductor element 1 of the power conversion apparatus includes a plurality of elements connected in parallel. Even in the case of the semiconductor element 1 including the plurality of elements, it suffices that the shunt resistor 12 is provided at one place in the stages preceding the gate resistors 111 and 112. Therefore, an abnormality in the semiconductor element 1 and its periphery can be detected without the necessity of providing each of the plurality of elements with a detection circuit that detects an abnormality in the driving state.

That is, with the power conversion apparatus according to the present embodiment, even in the case of adopting the semiconductor element 1 in which a plurality of elements are arranged in parallel, by using a single drive state detection circuit, an abnormality such as an overcurrent of the semiconductor element 1 and broken wiring between the gate driver 2 and the semiconductor element 1 can be detected. Therefore, according to the present embodiment, it is possible to suppress the manufacturing cost of the power conversion apparatus and realize high functionality.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A power conversion apparatus comprising:
a power conversion circuit including a semiconductor element arranged in each of an upper arm and a lower arm between DC links, the power conversion circuit being electrically connected to an AC load at an AC end between the upper arm and the lower arm;
a voltage detector configured to detect a voltage between the DC links;
a current detector configured to detect a current flowing in the AC end;
a control unit configured to generate a gate command for instructing operation of the semiconductor element based on a voltage value obtained by the voltage detector and a current value obtained by the current detector; and
a gate driver configured to drive the semiconductor element based on the gate command, the gate driver including a gate current detector configured to detect a gate current of the semiconductor element and a circuit configured to determine a drive state of the semiconductor element from the gate current, and outputting a value corresponding to the drive state to the control unit.

2. The power conversion apparatus according to claim 1, wherein the control unit detects an abnormality in the semiconductor element by comparing the gate command with the value corresponding to the drive state.

3. The power conversion apparatus according to claim 1, wherein the gate driver includes the gate current detector, a turn-on current detection circuit, a turn-off current detection circuit, and a logic circuit, the turn-on current detection circuit being configured to detect the gate current at a time of a turn-on of the semiconductor element by making a comparison with a positive threshold value with a direction in which the gate current flows from the gate driver into the semiconductor element as positive, the turn-off current detection circuit being configured to detect the gate current at a time of a turn-off of the semiconductor element by making a comparison with a negative threshold value, and the logic circuit being configured to generate the value corresponding to the drive state using a detection result of the turn-on current detection circuit and the turn-off current detection circuit.

4. The power conversion apparatus according to claim 3, wherein the control unit detects an abnormality in the semiconductor element by comparing the gate command with the value corresponding to the drive state.

5. The power conversion apparatus according to claim 3, wherein the logic circuit includes a set reset flip-flop circuit, a NOR gate circuit, and an EXOR gate circuit, and
an output of the turn-on current detection circuit is used as an input of a set terminal of the set reset flip-flop circuit and an input of the NOR gate circuit, an output of the turn-off current detection circuit is used as an input of a reset terminal of the set reset flip-flop circuit and an input of the NOR gate circuit, an inverted output of the set reset flip-flop circuit and an output of the NOR gate circuit are used as inputs of the EXOR gate circuit, and an output of the EXOR gate circuit is used as the value corresponding to the drive state of the semiconductor element.

6. The power conversion apparatus according to claim 5, wherein the control unit detects an abnormality in the semiconductor element by comparing the gate command with the value corresponding to the drive state.
